(19) United States
(12) Patent Application Publication
(10) Pub. No.: US 2024/0047925 A1
(43) Pub. Date: Feb. 8, 2024

(54) SHIELDING CAGE ASSEMBLY AND RECEPTACLE CONNECTOR ASSEMBLY WITH IMPROVED HEAT DISSIPATION PERFORMANCE

(71) Applicant: DONGGUAN LUXSHARE TECHNOLOGIES CO., LTD, Dongguan City (CN)

(72) Inventors: Baiyu DUAN, Dongguan City (CN); Rongzhe GUO, Dongguan City (CN); Hongji CHEN, Dongguan City (CN); Xiaokai WANG, Dongguan City (CN)

(73) Assignee: DONGGUAN LUXSHARE TECHNOLOGIES CO., LTD, Dongguan City (CN)

(21) Appl. No.: 18/113,768

(22) Filed: Feb. 24, 2023

(30) Foreign Application Priority Data
Aug. 4, 2022 (CN) 202210929720.0

(51) Int. Cl. H01R 13/659; H01R 13/6582

(52) U.S. Cl. CPC H01R 13/659; H01R 13/6582

(57) ABSTRACT

A shielding cage assembly includes a mating end surface and at least one group of stacked mating spaces. The mating spaces stacked in a same group are communicated at a rear of the shielding cage assembly to form a receiving space for accommodating a receptacle connector. The shielding cage assembly further includes an accommodating space between two adjacent mating spaces. The accommodating space extends through two opposite outer side walls of the shielding cage assembly. One side of the accommodating space extends through the mating end surface, and another side of the accommodating space extends to the receiving space. The shielding cage assembly is easy to assemble a heat dissipation member and has good heat dissipation performance. A receptacle connector assembly having the shielding cage assembly is also disclosed.

### CROSS-REFERENCE TO RELATED APPLICATION

This patent application claims priority of a Chinese Patent Application No. 202210929720.0, filed on Aug. 4, 2022 and titled “SHIELDING CAGE ASSEMBLY AND RECEPTACLE CONNECTOR ASSEMBLY”, the entire content of which is incorporated herein by reference.

### TECHNICAL FIELD

The present disclosure relates to a shielding cage assembly and a receptacle connector assembly, which belongs to a technical field of connectors.

### BACKGROUND

With the development of technology, the data transmission capacity of connectors is constantly improving. At the same time, the heat dissipation performance of the connectors needs to be improved accordingly.

### SUMMARY

An object of the present disclosure is to provide a shielding cage assembly and a receptacle connector assembly which are convenient for assembling a heat dissipation member.

In order to achieve the above object, the present disclosure adopts the following technical solution: a shielding cage assembly, including a mating end surface and at least one group of stacked mating spaces extending through the mating end surface; wherein the stacked mating spaces in a same group are communicated with each other at a rear of the shielding cage assembly so as to form a receiving space for receiving a receptacle connector; wherein the shielding cage assembly further includes an accommodating space located between two adjacent mating spaces in the stacked mating spaces, the accommodating space extends through two opposite outer side walls of the shielding cage assembly, one side of the accommodating space extends through the mating end surface, and another side of the accommodating space extends to the receiving space.

In order to achieve the above object, the present disclosure adopts the following technical solution: a receptacle connector assembly, including: a shielding cage assembly including a mating end surface and a mating space extending through the mating end surface, the shielding cage assembly being configured to be secured to a circuit board; a receptacle connector accommodated at a rear of the shielding cage assembly and communicating with the mating space, the receptacle connector being fixedly mounted to the circuit board; and a heat dissipation member fixedly mounted to the circuit board, the heat dissipation member having at least one surface exposed to the mating space, the at least one surface being configured to be able to closely abut against a plug connector which is inserted in the mating space and used in mating with the receptacle connector in a direction perpendicular to a board surface of the circuit board.

In order to achieve the above object, the present disclosure adopts the following technical solution: a receptacle connector assembly, including: a shielding cage assembly including a mating end surface and a mating space extending through the mating end surface, the shielding cage assembly being configured to be mounted to a circuit board; a receptacle connector accommodated at a rear of the shielding cage assembly and communicating with the mating space, the receptacle connector being mounted to the circuit board; and a heat dissipation member mounted to the circuit board, the heat dissipation member having at least one surface exposed to the mating space, the at least one surface being configured to be able to abut against a plug connector when the plug connector is inserted in the mating space; wherein the heat dissipation member includes a heat dissipation plate portion and a plurality of support columns connected with the heat dissipation plate portion, the plurality of support columns are configured to be supported on the circuit board; and wherein the heat dissipation plate portion includes a cavity, a liquid inlet hole and a liquid outlet hole, the liquid inlet hole and the liquid outlet hole communicate with the cavity to form a flow passage.

Compared with the prior art, by providing the accommodating space in the shielding cage assembly, the present disclosure facilitates the assembly of the shielding cage assembly with the heat dissipation member. The overall heat dissipation effect of the receptacle connector assembly having the shielding cage assembly is good. The heat dissipation member in the receptacle connector assembly is used to be fixed to the circuit board, and the heat dissipation member is arranged to abut against the plug connector which is inserted into the mating space, so that the plug connector is positioned in a direction perpendicular to the board surface of the circuit board. This positioning method reduces tolerance accumulation and is therefore more precise.

### BRIEF DESCRIPTION OF DRAWINGS

FIG. 1 is a schematic view of an exploded structure of a shielding cage assembly in accordance with an embodiment of the present disclosure, wherein a plurality of receptacle connectors are also shown;

FIG. 2 is a schematic view of an overall structure of the shielding cage assembly in accordance with an embodiment of the present disclosure;

FIG. 3 is a schematic view of part of the structure of the shielding cage assembly in accordance with an embodiment of the present disclosure;

FIG. 4 is a schematic exploded structural view of the shielding cage assembly of the present disclosure from another angle, wherein the receptacle connectors are also shown;

FIG. 5 is a schematic structural view of a top wall, a first outer side wall and a second outer side wall of the shielding cage assembly in accordance with an embodiment of the present disclosure;

FIG. 6 is a schematic structural view of FIG. 5 from another angle;

FIG. 7 is an enlarged schematic view of part A in FIG. 6;

FIG. 8 is an enlarged schematic view of part B in FIG. 6;

FIG. 9 is an enlarged schematic view of C part in FIG. 5;

FIG. 10 is an enlarged schematic view of part D in FIG. 5;

FIG. 11 is a schematic structural view of a bottom wall of the shielding cage assembly in accordance with an embodiment of the present disclosure;

FIG. 12 is an enlarged schematic view of part E in FIG. 11;

FIG. 13 is an enlarged schematic view of part F in FIG. 11;

FIG. 14 is a schematic structural view of a first intermediate wall of the shielding cage assembly in accordance with an embodiment of the present disclosure;

FIG. 15 is a schematic structural view of a second intermediate wall of the shielding cage assembly in accordance with an embodiment of the present disclosure;

FIG. 16 is a schematic structural view of a third side wall of the shielding cage assembly in accordance with an embodiment of the present disclosure;

FIG. 17 is a schematic structural view of a rear wall of the shielding cage assembly in accordance with an embodiment of the present disclosure;

FIG. 18 is a schematic structural view of a grounding elastic piece of the shielding cage assembly in accordance with an embodiment of the present disclosure;

FIG. 19 is a partial structural schematic view of a receptacle connector assembly in accordance with an embodiment of the present disclosure;

FIG. 20 is a partial enlarged schematic view of FIG. 19;

FIG. 21 is a schematic structural view of a receptacle connector of the receptacle connector assembly in accordance with an embodiment of the present disclosure;

FIG. 22 is a schematic perspective view showing an installation position of a plurality of heat dissipation members mounted to a circuit board in accordance with an embodiment of the present disclosure;

FIG. 23 is a schematic structural view of a heat dissipation member of the receptacle connector assembly in accordance with an embodiment of the present disclosure;

FIG. 24 is a schematic view of a structure of the heat dissipation member of the receptacle connector assembly in accordance with an embodiment of the present disclosure from a bottom view angle;

FIG. 25 is a schematic top view of some components of the receptacle connector assembly in accordance with an embodiment of the present disclosure;

FIG. 26 is a schematic cross-sectional view taken along line A-A in FIG. 25; and

FIG. 27 is a schematic structural view of a shell of the receptacle connector assembly in accordance with an embodiment of the present disclosure.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

The present disclosure discloses a shielding cage assembly 1 and a receptacle connector assembly.

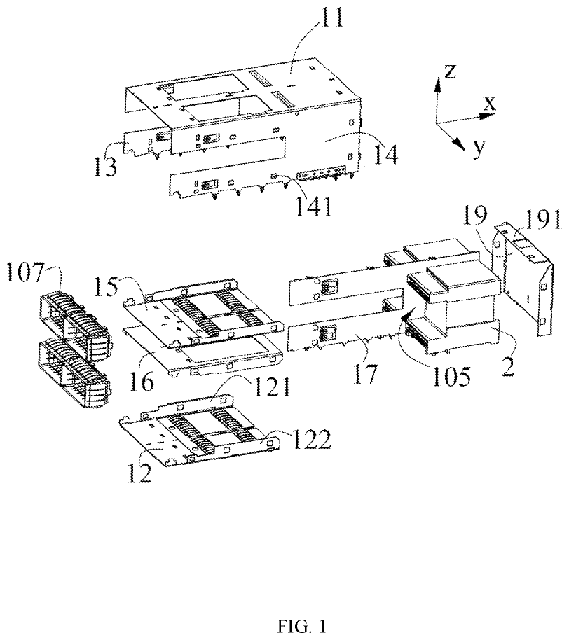

The technical solutions disclosed in the present disclosure will be introduced as follows with reference to the accompanying drawings. An end-to-end extension direction of the shielding cage assembly 1 involved in the description is a longitudinal direction, that is, a direction indicated by the x-axis in FIG. 1. In directions involved in the following description, a positive direction of the z-axis is upward, a negative direction of the z-axis is downward, a positive direction of the y-axis is forward, and a negative direction of the y-axis is backward.

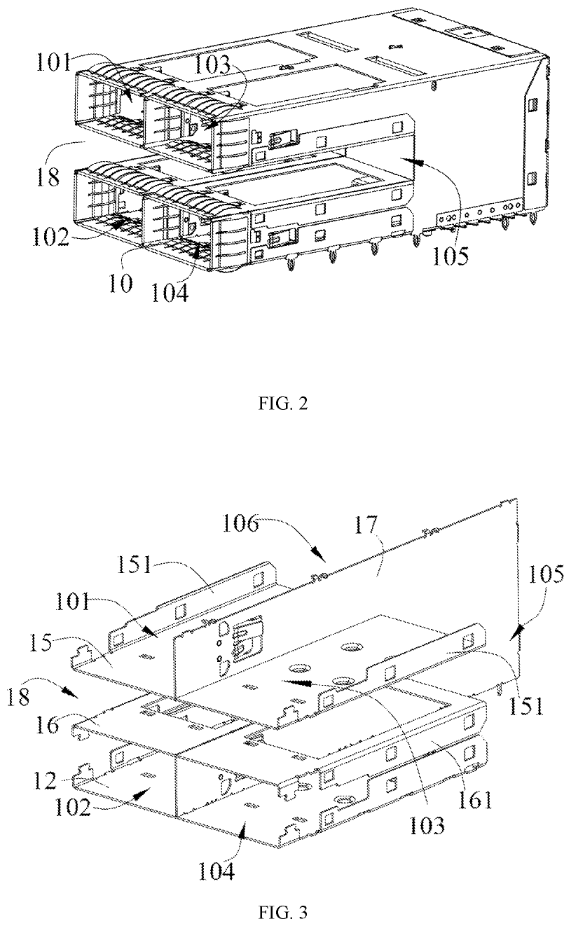

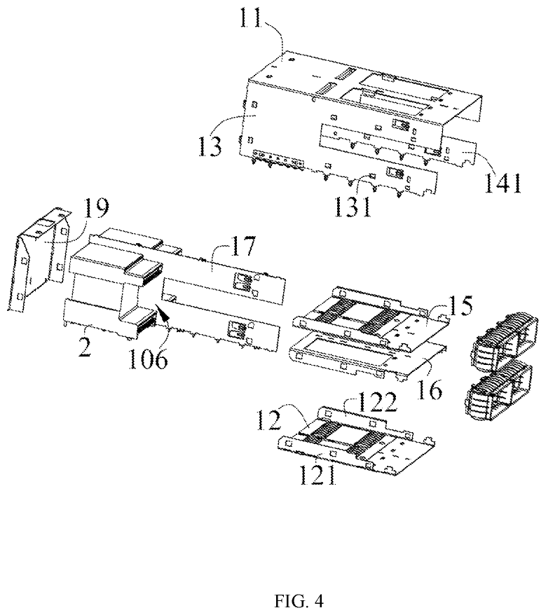

Referring to FIG. 2 and FIG. 3, the shielding cage assembly 1 includes a mating end surface 10 (e.g., a front end face) and at least one group of stacked mating spaces (corresponding to reference numerals 101, 102 and 103, 104) extending through the mating end surface 10. The stacked mating spaces are communicated at a rear of the shielding cage assembly 1 to form a receiving space (corresponding to reference numerals 106 and 105).

In the illustrated embodiment, four mating spaces are provided, which are a first mating space 101, a second mating space 102, a third mating space 103 and a fourth mating space 104. The first mating space 101 and the second mating space 102 are stacked. The first mating space 101 and the second mating space 102 are communicated at a rear of the shielding cage assembly 1 to form a first receiving space 106. The third mating space 103 and the fourth mating space 104 are stacked. The third mating space 103 and the fourth mating space 104 are communicated at the rear of the shielding cage assembly 1 to form a second receiving space 105.

Receptacle connectors 2 are placed in the first receiving space 106 and the second receiving space 105, respectively. Obviously, the receptacle connector 2 located in the first receiving space 106 is communicated with the first mating space 101 and the second mating space 102. The receptacle connector 2 located in the second receiving space 105 is communicated with the third mating space 103 and the fourth mating space 104.

The shielding cage assembly 1 further includes an accommodating space 18 which extends through two opposite outer side walls of the shielding cage assembly 1. One end of the accommodating space 18 extend through the mating end surface 10, and the other end of the accommodating space 18 extends to the first receiving space 106 and the second receiving space 105.

Referring to FIG. 1 to FIG. 3, the shielding cage assembly 1 includes a top wall 11, a bottom wall 12, a first outer side wall 13, a second outer side wall 14, a first intermediate wall 15, a second intermediate wall 16 and a third side wall 17.

The first mating space 101 is surrounded by the top wall 11, the first outer side wall 13, the first intermediate wall 15 and the third side wall 17. The second mating space 102 is surrounded by the bottom wall 12, the third side wall 17, the second intermediate wall 16 and the first outer side wall 13. The third mating space 103 is surrounded by the top wall 11, the third side wall 17, the first intermediate wall 15 and the second outer side wall 14. The fourth mating space 104 is surrounded by the second intermediate wall 16, the third side wall 17, the bottom wall 12 and the second outer side wall 14.

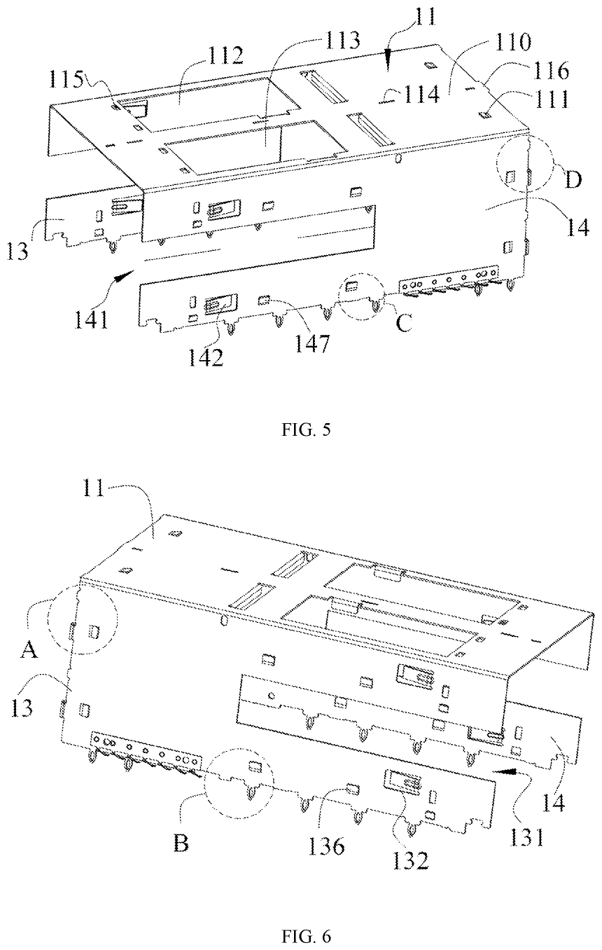

Referring to FIG. 5, the top wall 11 includes a first body portion 110 which is substantially flat. The first body portion 110 defines a through hole communicating with an outside of the shielding cage assembly 1 and the mating space in the shielding cage assembly 1. In the illustrated embodiment, the first body portion 110 defines a first through hole 112 and a second through hole 113. The first through hole 112 communicates with the outside and the first mating space 101. The second through hole 113 communicates with the outside and the third mating space 103. A first positioning tab 111 is provided at a position of the first body portion 110 adjacent to a rear end of the shielding cage assembly 1 in a manner of protruding toward the outside of the shielding cage assembly 1. A fifth abutting edge 116 is provided at a wall end of the first body portion 110 adjacent to the rear end of the shielding cage assembly 1. A plurality of first positioning grooves 114 are defined in the middle of the first body portion 110 along the longitudinal direction. A plurality of second positioning grooves 115 are defined in a position of the first body portion 110 adjacent to a front end of the shielding cage assembly 1. A plurality of the second positioning grooves 115 are arranged along a front-rear direction.

The first outer side wall 13 and the second outer side wall 14 are extended from two opposite sides of the first body portion 110 along a direction perpendicular to the first body portion 110.

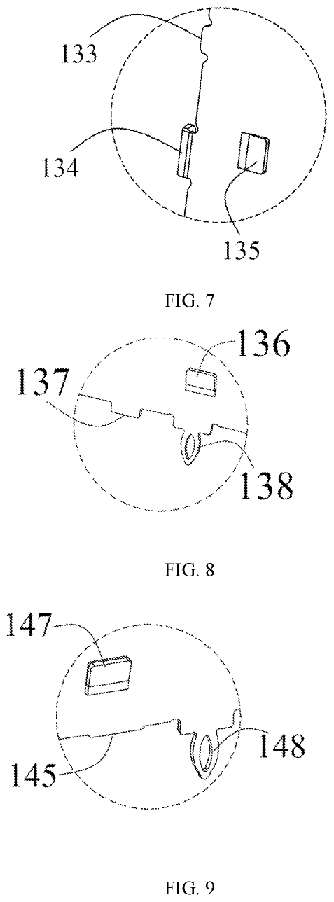

Referring to FIG. 6 to FIG. 8, the first outer side wall 13 is generally of a concaved configuration and is generally in a shape of a plate. A first recessed portion 131 of the first outer side wall 13 corresponds to the accommodating space 18. It can be considered that the accommodating space 18 is formed extending through the first outer side wall 13. First abutting elastic pieces 132 are provided on both the upper side and the lower side of the first recessed portion 131 of the first outer side wall 13. The first abutting elastic pieces 132 protrude into an interior of the mating space. A first abutting edge 133 and a first locking tongue 134 are provided on a wall end of the first outer side wall 13 adjacent to the rear end of the shielding cage assembly 1. The first abutting edge 133 is used for abutting against adjacent components to achieve positioning. The first locking tongue 134 protrudes outward from the first outer side wall 13, and is bent and pressed against a component surface which is locked with the first outer side wall 13, so as to realize the locking of the first outer side wall 13 and the component. Similarly, a second abutting edge 137 is provided on a side of the first outer side wall 13 adjacent to the bottom wall 12. The second abutting edge 137 is also used for abutting against adjacent components to achieve positioning. A plurality of second positioning tabs 135 and a plurality of third positioning tabs 136 are provided at the wall end of the first outer side wall 13 adjacent to the rear end of the shielding cage assembly 1, and at the wall end of the first outer side wall 13 adjacent to the bottom wall 12, respectively. The second positioning tabs 135 and the third positioning tabs 136 are formed in the form of protruding toward the outside of the shielding cage assembly 1. Furthermore, a side of the first outer side wall 13 adjacent to the bottom wall 12 has a first mounting tail 138. The first mounting tail 138 is formed by extending a side of the first outer side wall 13 adjacent to the bottom wall 12 toward the bottom wall 12. The first mounting tail 138 can be engaged in a mounting hole of a printed circuit board 4.

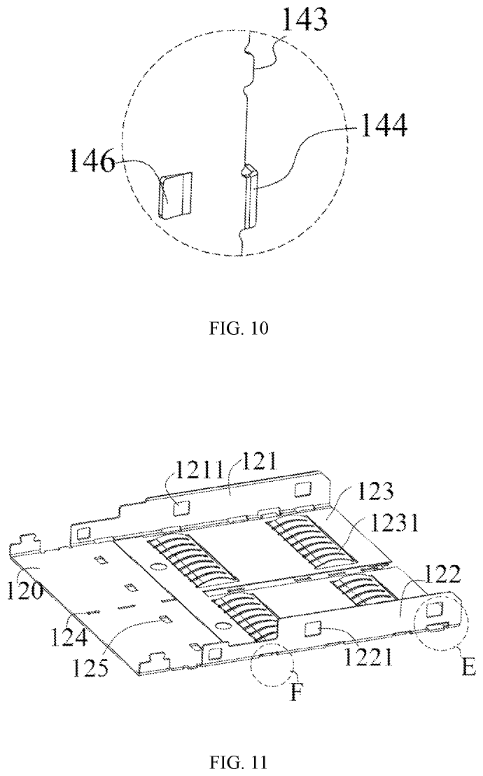

Similarly, referring to FIG. 5, FIG. 9 and FIG. 10, the second outer side wall 14 is generally of a concaved configuration and is generally in a shape of a plate. A second recessed portion 141 of the second outer side wall 14 corresponds to the accommodating space 18. It can be considered that the accommodating space 18 is formed extending through the second outer side wall 14. Second abutting elastic pieces 142 are provided on both the upper side and the lower side of the second recessed portion 141 of the second outer side wall 14. The second abutting elastic pieces 142 protrude into an interior of the mating space. A third abutting edge 143 and a second locking tongue 144 are provided on the wall end of the second outer side wall 14 adjacent to the rear end of the shielding cage assembly 1. The third abutting edge 143 is used for abutting against adjacent components to achieve positioning. The second locking tongue 144 protrudes outward from the second outer side wall 14, and is bent and pressed against a component surface which is locked with the second outer side wall 14, so as to realize the locking of the second outer side wall 14 and the component. Similarly, a fourth abutting edge 145 is provided on a side of the second outer side wall 14 adjacent to the bottom wall 12. The fourth abutting edge 145 is also used for abutting against adjacent components to achieve positioning. A plurality of fourth positioning tabs 146 and a plurality of fifth positioning tabs 147 are provided at the position of the second outer side wall 14 adjacent to the rear end of the shielding cage assembly 1 and at the position of the second outer side wall 14 adjacent to the bottom wall 12, respectively. The fourth positioning tabs 146 and the fifth positioning tabs 147 are formed in the form of protruding toward the outside of the shielding cage assembly 1. Furthermore, a side of the second outer side wall 14 adjacent to the bottom wall 12 has a second mounting tail 148. The second mounting tail 148 is formed by extending a side of the second outer side wall 14 adjacent to the bottom wall 12 toward the bottom wall 12. The second mounting tail 148 can be engaged in a mounting hole of the printed circuit board 4.

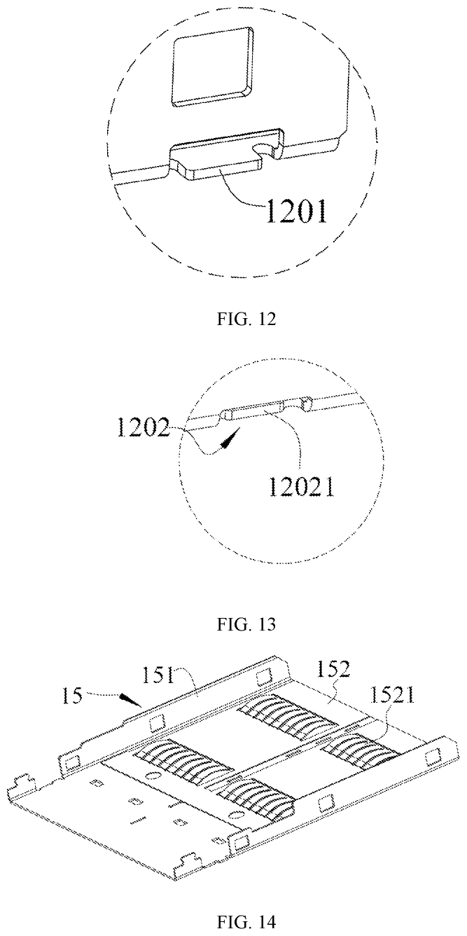

Referring to FIG. 1 and FIG. 11 to FIG. 13, the bottom wall 12 is spaced apart from the top wall 11. The bottom wall 12 includes a substantially flat second body portion 120. A first elastic piece 123 is fixed on a side of the second body portion 120 adjacent to the top wall 11, that is, on an upper surface of the second body portion 120 in the drawings. The first elastic piece 123 includes at least two arched protrusions 1231 in the longitudinal direction, that is, left and right directions in the drawings. The arched protrusion 1231 face the mating space where it is located. A plurality of third positioning grooves 124 are formed in the middle of the second body portion 120 along the longitudinal direction. A plurality of fourth positioning grooves 125 are defined at positions of the second body portion 120 adjacent to the mating end surface 10. The plurality of the fourth positioning grooves 125 are arranged along the front-rear direction. Two opposite side edges of the second body portion 120 extend in a direction perpendicular to the second body portion 120 to form a first extension edge 121 and a second extension edge 122. Fifth and sixth positioning grooves 1211 and 1221 are formed on the first extension edge 121 and the second extension edge 122. When the top wall 11 and the bottom wall 12 are installed, the third positioning tabs 136 located on the first outer side wall 13 will be fastened in the fifth positioning grooves 1211. The fifth positioning tabs 147 located on the second outer side wall 14 will be fastened in the sixth positioning grooves 1221. As a result, the top wall 11 and the bottom wall 12 are relatively fixed. In addition, first retaining edges 1201 are provided at the connection between the first extension edge 121 and the second body portion 120, and at the connection between the second extension edge 122 and the second body portion 120. Side surfaces of the first retaining edge 1201 facing the first and second outer side walls 13 and 14 are working surfaces. When the first and second outer side walls 13 and 14 are fastened on the bottom wall 12, the second abutting edge 137 and the fourth abutting edge 145 located on the first and second outer side walls 13 and 14 will abut against the working surface of the first retaining edge 1201. Escape portions 1202 are also provided at the connection between the second body portion 120 and the first extension edge 121, and at the connection between the second body portion 120 and the second extension edge 122. When the first and second outer side walls 13 and 14 are fastened to the bottom wall 12, the first and second mounting tails 138 and 138 located on the first and second outer side walls 13 and 14 148 passes through the escape portions 1202. Further, at least one second retaining edge 12021 may be included in the escape portion 1202. The second retaining edge 12021 abuts against the sides of the first and second mounting tails 138 and 148.

Relative fixing manners of the bottom wall 12 and the first outer side wall 13, and relative fixing manners of the bottom wall 12 and the second outer side wall 14 include but are not limited to snap connection, soldering, welding, and fastening with mechanical fasteners.

In width, the top wall 11 and the bottom wall 12 are similar in size, so that the first and second outer side walls 13 and 14 can abut against the corresponding first and second extension edges 121 and 122. The bottom wall 12 is shorter than the top wall 11 in length. One end of the bottom wall 12 in the longitudinal direction extends to the mating end surface 10 and becomes part of the mating end surface 10, and the other end extends to the first and second receiving spaces 106 and 105.

Referring to FIG. 1 and FIG. 14, the first intermediate wall 15 and the second intermediate wall 16 are arranged in parallel at intervals. Both the first intermediate wall 15 and the second intermediate wall 16 are substantially parallel to the top wall 11 and the bottom wall 12. The term “parallel” here means that body plate portions of the components are parallel.

Both the first intermediate wall 15 and the second intermediate wall 16 have one end extending to the mating end surface 10 and become part of the mating end surface 10, and the other end extending to the first and second receiving spaces 106 and 105.

The opposite side edges of the first intermediate wall 15 extend vertically toward the top wall 11 to form third extension edges 151. The third extension edges 151 located on both sides of the first intermediate wall 15 are buckled with the first outer side wall 13 and the second outer side wall 14, respectively. Thus, the space surrounded by the top wall 11, the first outer side wall 13 and the second outer side wall 14 is partially closed.

The width of the first intermediate wall 15 is similar to that of the top wall 11, so that the third extension edge 151 is in a state of abutting and covering with the first outer side wall 13 and the second outer side wall 14. Furthermore, the structures similar to the positioning grooves and the positioning tabs between the first and second outer side walls 13 and 14, and the bottom wall 12 are arranged to be fastened to each other.

A second elastic piece 152 is fixed on the surface of the first intermediate wall 15 facing the top wall 11. The second elastic piece 152 includes at least two arched protrusions 1521 in the longitudinal direction, that is, in the left-right direction in the drawings. The arched protrusion 1521 faces the mating space where it is located.

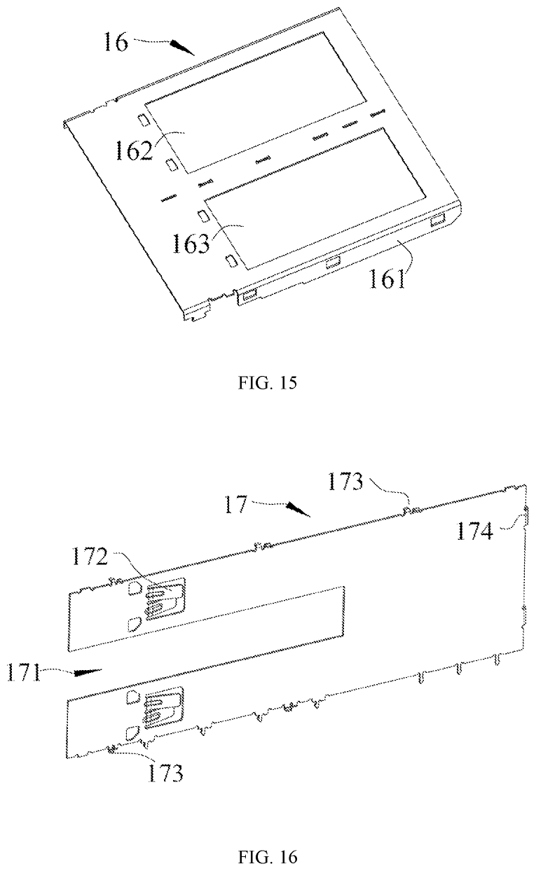

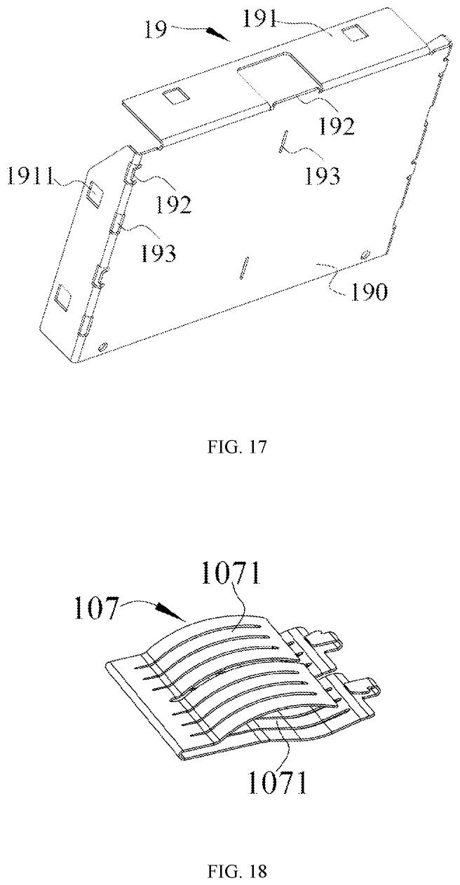

Referring to FIG. 15, opposite side edges of the second intermediate wall 16 extend vertically toward the bottom wall 12 to form fourth extension edges 161. The fourth extension edges 161 located on both sides of the second intermediate wall 16 are buckled with the first outer side wall 13 and the second outer side wall 14, respectively. Thus, the space surrounded by the bottom wall 12, the first outer side wall 13, and the second outer side wall 14 is partially closed.

Similarly, the width of the second intermediate wall 16 is similar to that of the bottom wall 12, so that the fourth extension edge 161 is in a state of abutting and covering with the first outer side wall 13 and the second outer side wall 14.

The positioning and connection structure between the second intermediate wall 16 and the first and second outer side walls 13 and 14 are similar to those between the bottom wall 12 and the first and second outer side walls 13 and 14.

The second intermediate wall 16 defines a through hole communicating with an outside of the shielding cage assembly 1 and the mating space. In the illustrated embodiment, the second intermediate wall 16 defines a third through hole 162 and a fourth through hole 163. The third through hole 162 communicates with the outside and the second mating space 102. The fourth through hole 163 communicates with the outside and the fourth mating space 104.

The accommodating space 18 between the first intermediate wall 15 and the second intermediate wall 16 is a continuous space. The accommodating space 18 extends through the first outer side wall 13 located at one outermost side of the shielding cage assembly 1, the second outer side wall 14 located at the other outermost side, and all walls located between the first outer side wall 13 and the second outer side wall 14.

Referring to FIG. 1 and FIG. 16, the third side wall 17 is located between the first outer side wall 13 and the second outer side wall 14. The third side wall 17 is substantially parallel to the first outer side wall 13 and the second outer side wall 14. The third side wall 17 separates a space between the first outer side wall 13 and the second outer side wall 14. The third side wall 17 is generally of a concaved configuration, and includes a third recessed portion 171. The third recessed portion 171 corresponds to the accommodating space 18. It can be considered that the accommodating space 18 is formed extending through the third side wall 17. One end of the third side wall 17 extends toward the mating end surface 10 and becomes part of the mating end surface and the other end extends to the rear end of the shielding cage assembly 1. The longitudinal length of the third side wall 17 is equivalent to the longitudinal length of the top wall 11. Different receptacle connectors 2 are arranged on two sides of the third side wall 17.

Upper and lower sides of the third recessed portion 171 are provided with abutting elastic piece groups 172. Each abutting elastic piece group 172 includes at least two abutting elastic pieces protruding in different directions. The aforementioned different directions refer to the directions of the front and rear sides of the third side wall 17. The front and rear sides of the third side wall 17 are different mating spaces. The abutting elastic pieces in the abutting elastic piece group 172 protruding in different directions will abut against the plug connectors which are assembled in different mating spaces.

A third locking tongue 173 is provided at the end of the third side wall 17 adjacent to the top wall 11 and the bottom wall 12. The wall end of the third side wall 17 adjacent to the rear end of the shielding cage assembly 1 is provided with a fourth locking tongue 174. The third and fourth locking tongues 173 and 174 are locked in the same manner as the first and second locking tongues 134 and 144 mentioned above. The third locking tongue 173 protrudes from the top wall 11 and the bottom wall 12 through the first positioning groove 114 and the third positioning groove 124 on the top wall 11 and the bottom wall 12. The third locking tongue 173 is bent and fitted to the upper surface of the top wall 11 and the lower surface of the bottom wall 12 to lock the third side wall 17 with the top wall 11 and the bottom wall 12.

A wall end of the third side wall 17 adjacent to the bottom wall 12 is also provided with a mounting tail for being mounted to a circuit board.

The shielding cage assembly 1 also includes a rear wall 19. The rear wall 19 is connected to the top wall 11, the first outer side wall 13, the second outer side wall 14 and the third side wall 17, thereby closing the rear end of the shielding cage assembly 1. The rear wall 19 includes a generally flat third body portion 190. Wall ends of the third body portion 190 adjacent to the top wall 11, the first outer side wall 13 and the second outer side wall 14 respectively protrude toward the top wall 11, the first outer side wall 13 and the second outer side wall 14 so as to form a plurality of fifth extension edges 191. The fifth extension edges 191 are attached to the outer surfaces of the top wall 11, the first outer side wall 13 and the second outer side wall 14. A plurality of sixth positioning grooves 1911 are defined on the fifth extension edges 191 to be buckled with the first positioning tab 111, the second positioning tab 135 and the fourth positioning tab 146 located at the corresponding positions of the top wall 11, the first outer side wall 13 and the second outer side wall 14. A third retaining edge 192 is provided at the connection between the third body portion 190 and the fifth extension edge 191. The third retaining edge 192 abuts against the fifth abutting edge 116, the first abutting edge 133 and the third abutting edge 143 at the corresponding positions of the top wall 11, the first outer side wall 13 and the second outer side wall 14, respectively, to achieve positioning. A plurality of seventh positioning grooves 193 are correspondingly provided at positions of the third body portion 190 near the wall ends of the first, second, and third side walls 13, 14, and 17. The first locking tongue 134, the second locking tongue 144 and the fourth locking tongue 174 located at the wall ends of the first, second and third side walls 13, 14 and 17 protrude beyond the rear wall 19 through the seventh positioning grooves 193, and then bend and fit to the outer surface of the rear wall 19.

Referring to FIG. 1 and FIG. 18, the shielding cage assembly 1 further includes a plurality of grounding elastic pieces 107. Each of the grounding elastic pieces 107 includes two elastic pieces 1071 which are arched in opposite directions. The plurality of the grounding elastic pieces 107 are respectively locked on wall ends of the top wall 11, the bottom wall 12, the first outer side wall 13, the second outer side wall 14, the first intermediate wall 15, the second intermediate wall 16 and the third side wall 17 which are adjacent to the mating end surface 10. The two elastic pieces 1071 are respectively located on both sides of the aforementioned walls.

The grounding elastic pieces 107 are fixed on the top wall 11 through the second positioning grooves 115. The grounding elastic pieces 107 are fixed on the bottom wall 12 through the fourth positioning grooves 125. Similarly, the grounding elastic pieces 107 on other walls are fixed in a similar manner, which will not be repeated.

The shielding cage assembly 1 can be made of metal materials, electroplated plastics, or filling materials etc.

In the embodiment described above, the shielding cage assembly 1 includes four mating spaces: a first mating space 101, a second mating space 102, a third mating space 103 and a fourth mating space 104. The first mating space 101 and the second mating space 102 are formed as a group, and the two mating spaces are stacked. The third mating space 103 and the fourth mating space 104 are formed as a group, and the two mating spaces are stacked. The two groups of stacked mating spaces are separated by the third side wall 17. Obviously, in other embodiments, the shielding cage assembly 1 may also include more than two groups of stacked mating spaces. Corresponding to this, it is only necessary to provide more side walls. For example, the shielding cage assembly 1 further includes a fourth side wall. The third side wall 17 and the fourth side wall separate the space between the first outer side wall 13 and the second outer side wall 14, and other conditions remain unchanged. Then, the shielding cage assembly 1 will include three groups of stacked mating spaces. Of course, in other embodiments, the stacked mating spaces may also be only one group. Correspondingly, the third side wall 17 is not required.

In the illustrated embodiment of the present disclosure, the shielding cage assembly 1 includes a set of the first intermediate wall 15 and the second intermediate wall 16. In other words, the shielding cage assembly 1 includes one accommodating space 18. The set of the first intermediate wall 15 and the second intermediate wall 16, or the one accommodating space 18 separates the space between the top wall 11 and the bottom wall 12, so that the shielding cage assembly 1 includes two stacked mating spaces. It is understandable to those skilled in the art that, in other embodiments, if there are more than one set of the first intermediate wall 15 and the second intermediate wall 16 or more than one accommodating space 18 is provided, the number of stacked mating spaces will also increase.

The shielding cage assembly 1 disclosed in the present disclosure includes at least one of the accommodating spaces 18 for accommodating a heat dissipation member.

The stacked mating spaces in the same group communicate with each other adjacent to a rear of the shielding cage assembly 1 to form receiving spaces, for example, the first receiving space 106 and the second receiving space 105. One receptacle connector is located in the receiving space. The receptacle connector includes multiple groups of connection ports. Each group of connection ports communicates with one of the stacked mating spaces.

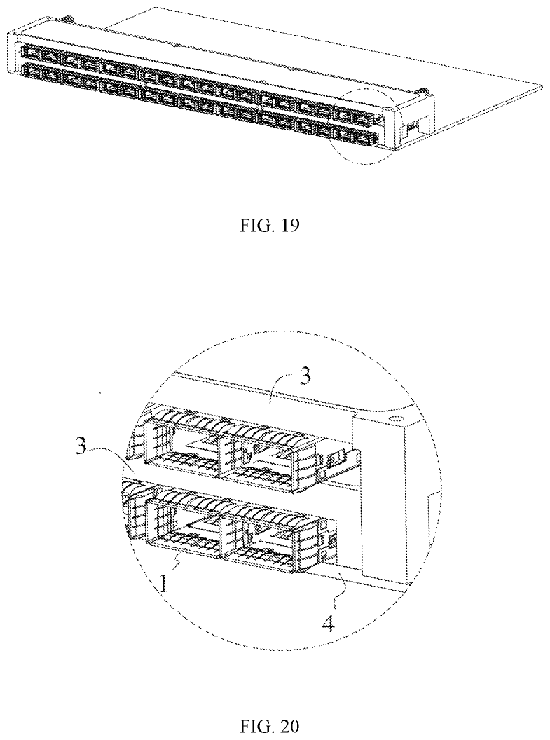

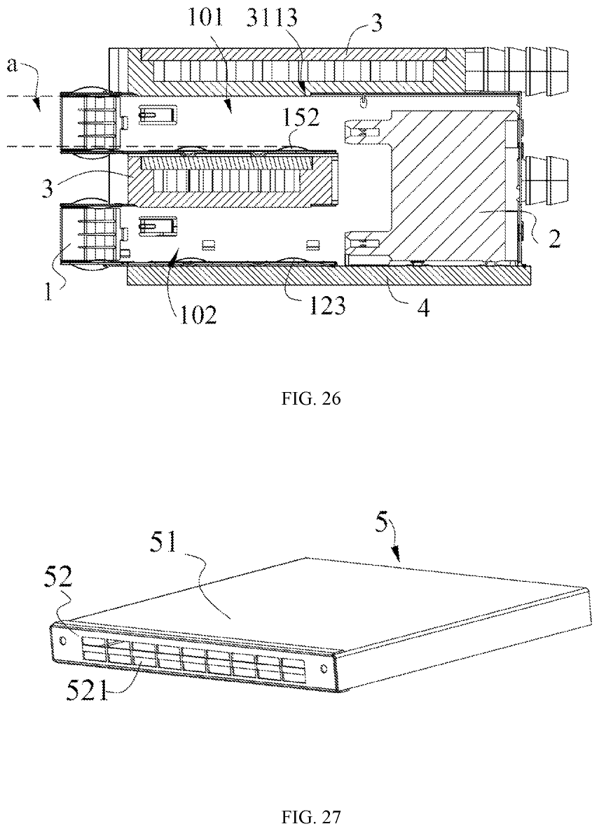

Referring to FIG. 19, FIG. 20 and FIG. 26, the present disclosure also discloses a receptacle connector assembly which includes a plurality of shielding cage assemblies 1 arranged in sequence, a plurality of receptacle connectors 2 located at a rear of the shielding cage assemblies 1 and mounted on a printed circuit board (PCB) 4, and a heat dissipation member 3. The shielding cage assemblies 1 are configured to be secured to the printed circuit board 4.

The shielding cage assembly 1 is the same as the shielding cage assembly 1 disclosed and described above.

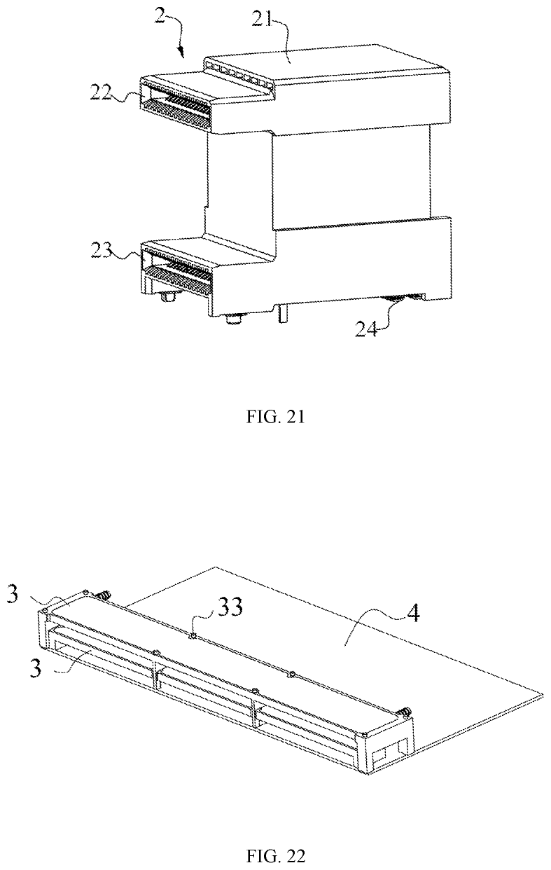

Referring to FIG. 21, the receptacle connector 2 includes a connector housing 21, two connection ports 22, 23 on one side of the connector housing 21, and a terminal module 24 at the bottom of the connector housing 21. Conductive terminals located in the connection ports 22 and 23 are electrically connected to the terminal module 24. The receptacle connector 2 is fixedly mounted on the printed circuit board 4 in a known mounting manner. The terminal module 24 is electrically connected to the printed circuit board 4.

The first connection port 22 and the second connection port 23 face different stacked mating spaces, respectively. For example, the first connection port 22 faces the first mating space 101, and the second connection port 23 faces the second mating space 102. Different plug connectors are inserted into the first mating space 101 and the second mating space 102 so as to mate with the first connection port 22 and the second connection port 23, respectively.

Referring to FIG. 20 and FIG. 22, in the illustrated embodiment, two heat dissipation members 3 are provided, in which one is located on the upper side of the shielding cage assembly 1, and the other is located in accommodating space 18 of the shielding cage assembly 1. A lower surface of a plate body portion of the heat dissipation member 3 located on the upper side is in contact with the top wall 11 of the shielding cage assembly 1. In the embodiment, the two heat dissipation members 3 are similar in structure. Therefore, the structure of one of the heat dissipation members 3 will be described in detail below with reference to the accompanying drawings.

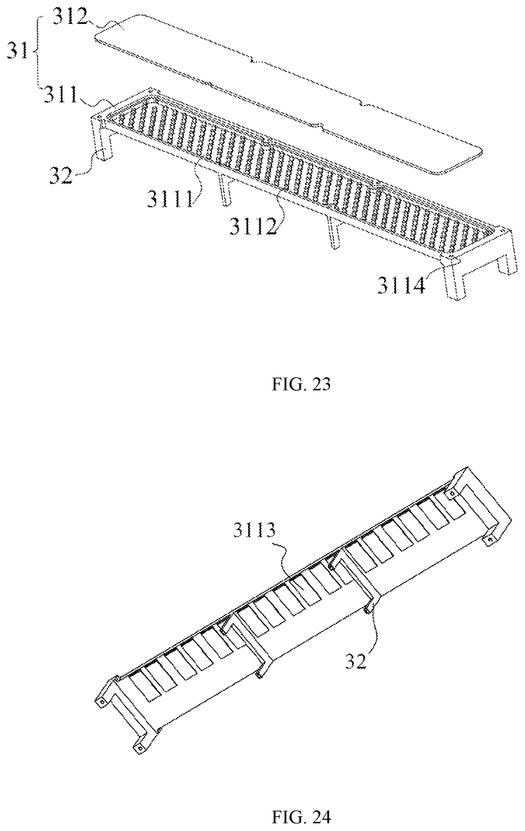

Referring to FIG. 23 and FIG. 24, the heat dissipation member 3 includes a heat dissipation plate portion 31 and a plurality of support columns 32 for fixing and supporting the heat dissipation plate portion 31 on the printed circuit board 4. The support columns 32 and the heat dissipation plate portion 31 may be integrally formed, which is considered to be a way of fixed connection. The support columns 32 and the heat dissipation plate portion 31 may also be formed separately and then fixedly connected together.

In the illustrated embodiment, the heat dissipation plate portion 31 includes a first heat dissipation plate 311 and a second heat dissipation plate 312 which is fixed and sealed with the first heat dissipation plate 311. The first heat dissipation plate 311 is recessed into its own plate to form a cavity 3111. The first heat dissipation plate 311 has a plurality of columnar protrusions 3112. The plurality of columnar protrusions 3112 are dispersedly arranged in the cavity 3111. The heat dissipation plate portion 31 further includes a liquid inlet hole and a liquid outlet hole (not numbered) which communicate with the cavity 3111 and the outside of the heat dissipation plate portion 31. The liquid inlet hole is located at one end of the first heat dissipation plate 311, and the liquid outlet hole is located at the other end of the first heat dissipation plate 311. When a cooling liquid enters the cavity 3111 through the liquid inlet hole, it flows through the entire cavity 3111 and then flows out from the liquid outlet hole. The columnar protrusions 3112 disturb the cooling liquid and increase the contact area between the first heat dissipation plate 311 and the cooling liquid, thereby promoting heat exchange between the heat dissipation plate portion 31 and the cooling liquid.

In the illustrated embodiment, the support column 32 and the first heat dissipation plate 311 are of an integral configuration. The first heat dissipation plate 311 is erected on the printed circuit board 4 through the support columns 32. Referring to FIG. 22 and FIG. 23, mounting through holes 3114 are provided on the first heat dissipation plate 311. The mounting through holes 3114 extend through the first heat dissipation plate 311 and the support columns 32. Screws 33 are used to pass through the mounting through holes 3114 to fix the first heat dissipation plate 311 on the printed circuit board 4.

In the foregoing embodiments, the mounting through holes 3114 are disposed at positions of the first heat dissipation plate 311 corresponding to the support columns 32. In other embodiments, the mounting through holes 3114 may be disposed at positions of the first heat dissipation plate 311 that do not correspond to the support columns 32. Alternatively, some of the mounting through holes 3114 are arranged at positions corresponding to the support columns 32, and some of the mounting through holes 3114 are arranged at positions not corresponding to the support columns 32.

In the foregoing embodiments, the mounting through holes 3114 are provided on the first heat dissipation plate 311. The second heat dissipation plate 312 avoids the mounting through holes 3114 through structural design. In other embodiments, the mounting through holes 3114 may extend through the first heat dissipation plate 311 and the second heat dissipation plate 312 at the same time. The screws 33 pass through the mounting through holes 3114 to fix the heat dissipation plate portion 31 on the printed circuit board 4, and at the same time fix the first heat dissipation plate 311 and the second heat dissipation plate 312.

In the foregoing embodiment, the cavity 3111 is formed by the first heat dissipation plate 311 being recessed into the plate itself. Optionally, the cavity 3111 may also be surrounded by multiple plates. In the foregoing embodiments, the liquid inlet hole and the liquid outlet hole are located at both ends of the first heat dissipation plate 311. Optionally, it may also be located at both ends of the second heat dissipation plate 312. Alternatively, in an embodiment that includes not only the first and second heat dissipation plates, the liquid outlet hole and the liquid inlet hole can be located on other plates, and are disposed at both ends of the heat dissipation plate portion 31, respectively.

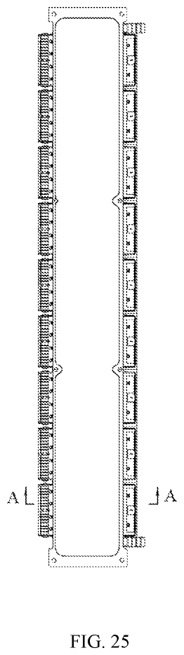

A bottom surface of the first heat dissipation plate 311 has protrusions 3113 extending outwardly perpendicular to a board surface of the first heat dissipation plate 311. After the heat dissipation member 3 is installed in the receptacle connector assembly, the protrusions 3113 will extend into the mating space through the first and second through holes 112 and 113, or the third and fourth through holes 162 and 163 in the shielding cage assembly 1. A side of the protrusions 3113 facing the board surface of the printed circuit board 4 is a working surface. The working surface is parallel to the board surface of the printed circuit board 4. Referring to FIG. 25 and FIG. 26, a minimum distance a between the working surface and the first elastic piece 123 or the second elastic piece 152 in the same mating space is smaller than a thickness of the plug connector at the corresponding position. Therefore, when the plug connector is inserted into the mating space, its upper surface will be in close contact with the working surface of the protrusions 3113.

Taking the first mating space 101 as an example, after the plug connector is inserted into the first mating space 101, the plug connector abuts against the working surface of the protrusions 3113 (which is a bottom wall of the protrusion 3113) protruding into the first mating space 101 under the elastic force of the second elastic piece 152. At the same time, the heat dissipation member 3 with the protrusions 3113 is directly fixed on the printed circuit board 4. That is, a distance between the plug connector and the printed circuit board 4 is individually positioned by the heat dissipation member 3.

In the related art, positioning of the plug connector is performed in the following manner. The plug connector abuts against the heat dissipation member 3. The heat dissipation member 3 is fixed to the shielding cage assembly 1. The shielding cage assembly 1 is fixed to the printed circuit board 4. As a result, the positioning of the plug connector in the direction perpendicular to the board surface of the printed circuit board 4 is realized. In this positioning method, many components are involved, and tolerances exist both within the components themselves and between the components. The accumulation of tolerances results in a large positional deviation of the plug connector and poor alignment with the receptacle connector.

In the present application, the heat dissipation member 3 is directly fixed to the printed circuit board 4, and the plug connector is positioned by abutting against the heat dissipation member 3. Compared with the positioning method in the related art, less components are involved, and the positional accuracy is high. With the acceleration of the transmission speed of the connector, the mating accuracy of the receptacle connector and the plug connector is getting higher and higher. Obviously, the higher the mating accuracy of the two, and the better the fit between the two, the more beneficial to transmission.

Referring to FIG. 27, the receptacle connector assembly further includes a shell 5. The shell 5 includes a shell main body 51 and a cover 52 fixedly connected with the shell main body 51. Other components of the receptacle connector assembly are received in the shell main body 51. The cover 52 defines a mounting hole 521 corresponding to the front end of the shielding cage assembly 1. The shielding cage assembly 1 is tightly installed in the mounting hole 521 through the elastic pieces 1071 located on the outer peripheral side of the shielding cage assembly 1.

The cover 52 is also provided with holes for installing cooling liquid pipes.

In the aforementioned embodiments of the receptacle connector assembly, the shielding cage assembly 1 is the shielding cage assembly having the accommodating space 18 disclosed in the present disclosure. It is easy to understand that, by replacing the shielding cage assembly with another member, such as a shielding cage assembly with one mating space, in the receptacle connector assembly, the advantages of directly fixing and supporting the heat dissipation member 3 on the printed circuit board 4 and performing high-precision positioning of the plug connector through the heat dissipation member 3 still exist.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A shielding cage assembly, comprising a mating end surface and at least one group of stacked mating spaces extending through the mating end surface;
wherein the stacked mating spaces in a same group are communicated with each other at a rear of the shielding cage assembly so as to form a receiving space for receiving a receptacle connector;
wherein the shielding cage assembly further comprises an accommodating space located between two adjacent mating spaces in the stacked mating spaces, the accommodating space extends through two opposite outer side walls of the shielding cage assembly, one side of the accommodating space extends through the mating end surface, and another side of the accommodating space extends to the receiving space.

2. The shielding cage assembly according to claim 1, further comprising a top wall and a bottom wall;
wherein the top wall, the bottom wall and the two opposite outer side walls are enclosed to form an outer frame of the shielding cage assembly;
wherein the top wall and one ends of the two opposite outer side walls extend to the mating end surface and become part of the mating end surface, the top wall and another ends of the two opposite outer side walls extend to a rear end of the shielding cage assembly; and
wherein one end of the bottom wall extends to the mating end surface and becomes part of the mating end surface, and another end of the bottom wall extends to the receiving space.

3. The shielding cage assembly according to claim 2, further comprising at least one group of a first intermediate wall and a second intermediate wall which are spaced apart from each other;
wherein two sides of the first intermediate wall are fixed to the two opposite outer side walls, respectively; one end of the first intermediate wall extends to the mating end surface and becomes part of the mating end surface, and another end of the first intermediate wall extends to the receiving space;
wherein two sides of the second intermediate wall are fixed to the two opposite outer side walls, respectively; one end of the second intermediate wall extends to the mating end surface and becomes part of the mating end surface, and another end of the second intermediate wall extends to the receiving space; and
wherein the accommodating space is located between the first intermediate wall and the second intermediate wall.

4. The shielding cage assembly according to claim 3, further comprising at least one third side wall, wherein the at least one third side wall is located between the two opposite outer side walls, and a space between the two opposite outer side walls is separated by the at least one third side wall.

5. The shielding cage assembly according to claim 3, further comprising a rear wall, wherein the rear wall is fixed to the top wall and/or the two opposite outer side walls, thereby closing a rear end of the shielding cage assembly.

6. The shielding cage assembly according to claim 3, wherein the mating spaces are enclosed by the bottom wall, the second intermediate wall and two adjacent side walls; or
the mating spaces are enclosed by the top wall, the first intermediate wall and the two adjacent side walls; or
the mating spaces are enclosed by the first intermediate wall, the second intermediate wall and the two adjacent side walls.

7. The shielding cage assembly according to claim 6, wherein elastic pieces are fixed on the bottom wall and an inner surface of the first intermediate wall, and the inner surface faces toward the mating space which is partially enclosed by the inner surface; an
wherein at least one of the elastic pieces is provided in each mating space which is enclosed by the bottom wall and the first intermediate wall.

8. The shielding cage assembly according to claim 7, wherein for each mating space, at least one through hole is correspondingly defined on the top wall opposite to the elastic pieces or correspondingly defined on the second intermediate wall.

9. A receptacle connector assembly, comprising:
a shielding cage assembly comprising a mating end surface and a mating space extending through the mating end surface, the shielding cage assembly being configured to be secured to a circuit board;
a receptacle connector accommodated at a rear of the shielding cage assembly and communicating with the mating space, the receptacle connector being fixedly mounted to the circuit board; and
a heat dissipation member fixedly mounted to the circuit board, the heat dissipation member having at least one surface exposed to the mating space, the at least one surface being configured to be able to closely abut against a plug connector which is inserted in the mating space and used in mating with the receptacle connector in a direction perpendicular to a board surface of the circuit board.

10. The receptacle connector assembly according to claim 9, wherein at least one group of the stacked mating spaces are provided extending through the mating end surface;
wherein the stacked mating spaces in a same group are communicated with each other at the rear of the shielding cage assembly so as to form a receiving space for receiving the receptacle connector;
wherein the shielding cage assembly further comprises an accommodating space located between two adjacent mating spaces in the stacked mating spaces, the accommodating space extends through two opposite outer side walls of the shielding cage assembly, one side of the accommodating space extends through the mating end surface, and another side of the accommodating space extends to the receiving space; and
wherein a plurality of the heat dissipation members are provided, and the plurality of the heat dissipation members are disposed on an upper surface of the top wall of the shielding cage assembly and in the accommodating space, respectively.

11. The receptacle connector assembly according to claim 9, wherein the heat dissipation member comprises a heat dissipation plate portion and a support column fixedly connected with the heat dissipation plate portion; and
wherein the heat dissipation plate portion comprises a cavity, a liquid inlet hole and a liquid outlet hole, the liquid inlet hole and the liquid outlet hole are provided at two ends of the heat dissipation plate portion, respectively.

12. The receptacle connector assembly according to claim 11, wherein the heat dissipation plate portion comprises a plurality of columnar protrusions which are dispersedly disposed in the cavity.

13. The receptacle connector assembly according to claim 11, wherein the heat dissipation member further comprises a screw, the heat dissipation plate portion has a mounting through hole, and the screw passes through the mounting through hole to fix the heat dissipation plate portion to the circuit board.

14. The receptacle connector assembly according to claim 9, wherein the heat dissipation member comprises a protrusion on a surface adjacent to the mating space, the protrusion protrudes into the mating space and has a working surface parallel to the circuit board;
wherein an elastic piece is provided on a side of the mating space, and the side of the mating space is opposite to the working surface of the protrusion; and
wherein a minimum distance between the protrusion and the elastic piece is smaller than a thickness of the plug connector at a corresponding position.

15. The receptacle connector assembly according to claim 9, further comprising a shell in which the shielding cage assembly, the receptacle connector and the heat dissipation member are enclosed.

16. The receptacle connector assembly according to claim 15, wherein a cover of the shell is provided with a mounting hole corresponding to a mating end of the shielding cage assembly; and wherein the shielding cage assembly is tightly mounted in the mounting hole through a grounding elastic piece which is located at the mating end of the shielding cage assembly.

17. A receptacle connector assembly, comprising:
a shielding cage assembly comprising a mating end surface and a mating space extending through the mating end surface, the shielding cage assembly being configured to be mounted to a circuit board;
a receptacle connector accommodated at a rear of the shielding cage assembly and communicating with the mating space, the receptacle connector being mounted to the circuit board; and
a heat dissipation member mounted to the circuit board, the heat dissipation member having at least one surface exposed to the mating space, the at least one surface being configured to be able to abut against a plug connector when the plug connector is inserted in the mating space;
wherein the heat dissipation member comprises a heat dissipation plate portion and a plurality of support columns connected with the heat dissipation plate portion, the plurality of support columns are configured to be supported on the circuit board; and
wherein the heat dissipation plate portion comprises a cavity, a liquid inlet hole and a liquid outlet hole, the liquid inlet hole and the liquid outlet hole communicate with the cavity to form a flow passage.

18. The receptacle connector assembly according to claim 17, wherein the flow passage is configured to flow a cooling liquid which flows into the cavity from the liquid inlet hole and flows out of the cavity from the liquid outlet hole; and wherein heat generated by mating of the plug connector and the receptacle connector is at least partially transferred into the cooling liquid.

19. The receptacle connector assembly according to claim 17, wherein the heat dissipation plate portion comprises a plurality of columnar protrusions which are dispersedly disposed in the cavity.

20. The receptacle connector assembly according to claim 17, wherein the heat dissipation member comprises a protrusion on a surface adjacent to the mating space, the protrusion protrudes into the mating space and has a working surface parallel to the circuit board;
wherein an elastic piece is provided on a side of the mating space, and the side of the mating space is opposite to the working surface of the protrusion; and
wherein a minimum distance between the protrusion and the elastic piece is smaller than a thickness of the plug connector at a corresponding position.
